(19) United States
(12) Patent Application Publication
(10) Pub. No.: US 2026/0151872 A1
(43) Pub. Date: Jun. 4, 2026

(54) HYBRID ABRASIVE SYSTEM FOR RU CMP

(71) Applicant: Taiwan Semiconductor Manufacturing Co., Ltd., Hsinchu (TW)

(72) Inventors: Jin-Hao Jhang, Chubei City (TW); Ku-Feng Yang, Baoshan Township (TW); Chu-Hsuan Sha, Taipei City (TW); Szuya Liao, Zhubei (TW)

(21) Appl. No.: 19/277,069

(22) Filed: Jul. 22, 2025

Related U.S. Application Data
(63) Continuation of application No. 18/678,910, filed on May 30, 2024.
(60) Provisional application No. 63/626,309, filed on Jan. 29, 2024.

(51) Int. Cl. B24B 37/04; H10P 52/40; H10P 95/00

(52) U.S. Cl. CPC B24B 37/044; H10P 52/403; H10P 95/062

(57) ABSTRACT

In an embodiment, a method includes forming an opening in a dielectric layer; filling the opening with a conductive material; and performing a chemical mechanical polishing process on the conductive material and the dielectric layer, the chemical mechanical polishing process comprising a slurry, the slurry comprising: abrasives, the abrasives comprising titania-silica hybrid particles; and an oxidizer.

### PRIORITY CLAIM AND CROSS-REFERENCE

This application is a continuation of U.S. patent application Ser. No. 18/678,910, filed on May 30, 2024, entitled “Hybrid Abrasive System for RU CMP,” which claims the benefit of the U.S. Provisional Application No. 63/626,309, filed on Jan. 29, 2024, entitled “Titania-Silica Hybrid Abrasive System For Ru CMP,” which application is hereby incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

Fin Field-Effect Transistor (FinFET) devices are becoming commonly used in integrated circuits. FinFET devices have a three-dimensional structure that comprises a semiconductor fin protruding from a substrate. A gate structure, configured to control the flow of charge carriers within a conductive channel of the FinFET device, wraps around the semiconductor fin. For example, in a tri-gate FinFET device, the gate structure wraps around three sides of the semiconductor fin, thereby forming conductive channels on three sides of the semiconductor fin.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a Fin Field-Effect Transistor (FinFET) device, in accordance with some embodiments.

FIGS. 2-6, 7A-7C, 8-16, and 19 illustrate various cross-sectional views of a FinFET device at various stages of fabrication, in accordance with some embodiments.

FIGS. 17A-17E illustrate features of a chemical mechanical polishing system, in accordance with some embodiments.

FIGS. 18A-18D illustrate processes for forming chemical mechanical polishing abrasives, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same reference numeral in different figures refers to the same or similar component formed by a same or similar method using a same or similar material(s).

Embodiments of the present disclosure are discussed in the context of forming a FinFET device, and in particular, in the context of forming contact plugs for a FinFET device. Although the disclosed embodiments are discussed using FinFET device as an example, the disclosed methods may also be used in other types of devices, such as planar devices, gate all around (GAA) devices, or CFET devices. In addition, although the disclosed embodiments are discussed in detail using a contact plug as an example, the disclosed methods may also be used in other conductive features, such as metallization layers of an interconnect structure.

The disclosed embodiments provide forming semiconductor devices (e.g., transistors) over a semiconductor substrate and forming an interconnect structure (e.g., contacts and metallization layers) in electrical connection with the semiconductor devices. For example, a contact to a semiconductor device may be formed through an inter-layer dielectric (ILD) layer by first forming a dielectric layer (e.g., an oxide material) over the ILD layer, patterning an opening through the dielectric layer and the ILD layer to expose a feature of the semiconductor device, filling the opening with a conductive material, and performing one or more chemical mechanical polishing (CMP) processes to remove portions of the conductive material and the dielectric layer. The CMP processes may utilize a slurry with hybrid abrasives which include multiple materials to achieve advantages.

For example, in embodiments in which the conductive material comprises ruthenium, the abrasives may include titania and silica material. In some embodiments, the abrasives may include titania-silica hybrid particles, wherein each titania-silica hybrid particle has a titania structure and a silica structure. In addition, the titania-silica hybrid particles may have an alternative structure (e.g., a material distinct from titania and silica) and a titania structure, or an alternative structure and a silica structure. By performing the CMP process with abrasives having the titania material in close proximity with the silica material, both ruthenium and dielectric material (e.g., silicon oxide) may be removed efficiently and at proportionate rates to one another. As a result, the CMP process may be performed with increased efficiency, effectiveness, and yield.

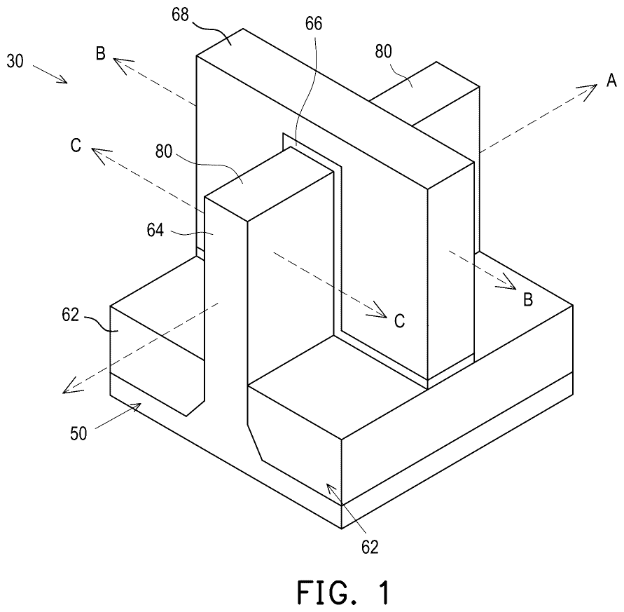

FIG. 1 illustrates an example of a FinFET 30 in a perspective view. The FinFET 30 includes a substrate 50 and a fin 64 protruding above the substrate 50. Isolation regions 62 are formed on opposing sides of the fin 64, with the fin 64 protruding above the isolation regions 62. A gate dielectric 66 is along sidewalls and over a top surface of the fin 64, and a gate electrode 68 is over the gate dielectric 66. Source/drain regions 80 are in the fin 64 and on opposing sides of the gate dielectric 66 and the gate electrode 68. FIG. 1 further illustrates reference cross-sections that are used in later figures. Cross-section B-B extends along a longitudinal axis of the gate electrode 68 of the FinFET 30. Cross-section A-A is perpendicular to cross-section B-B and is along a longitudinal axis of the fin 64 and in a direction of, e.g., a current flow between the source/drain regions 80. Cross-section C-C is parallel to cross-section B-B and is across the source/drain region 80. Subsequent figures refer to these reference cross-sections for clarity.

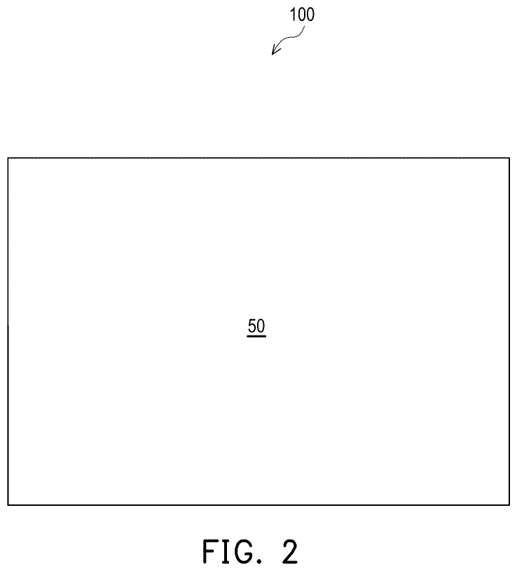

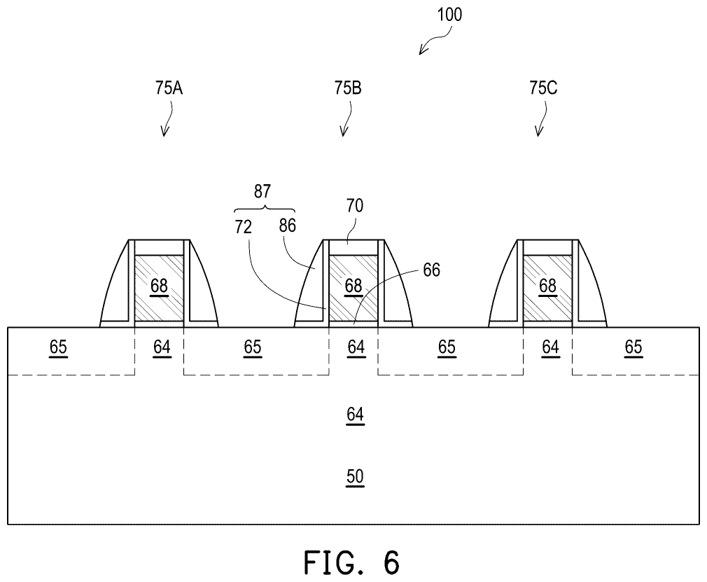

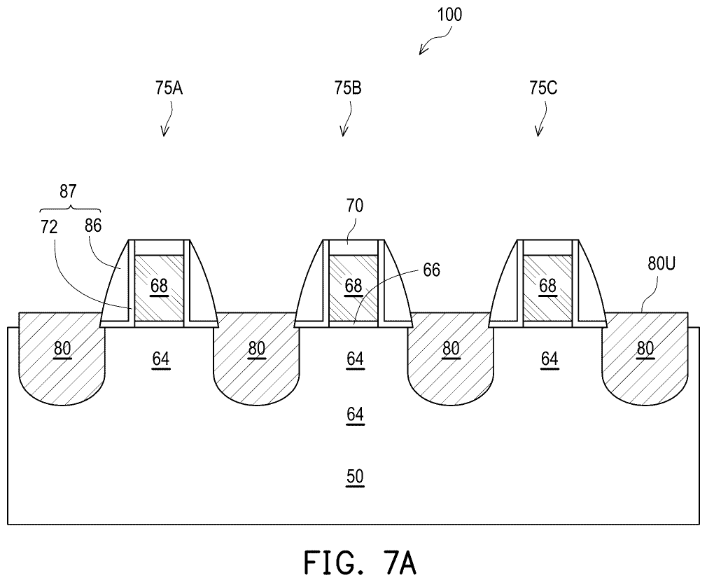

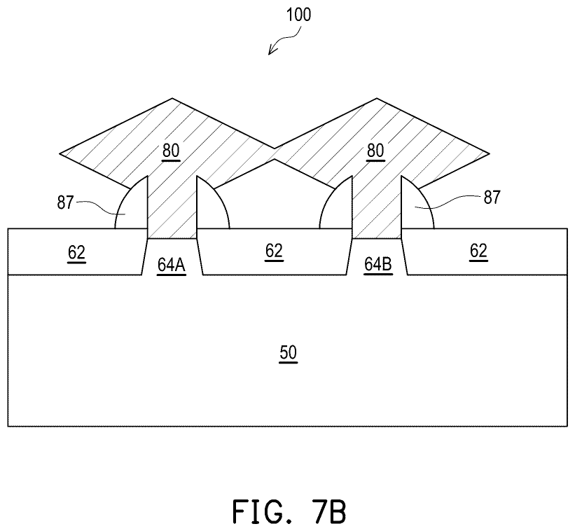

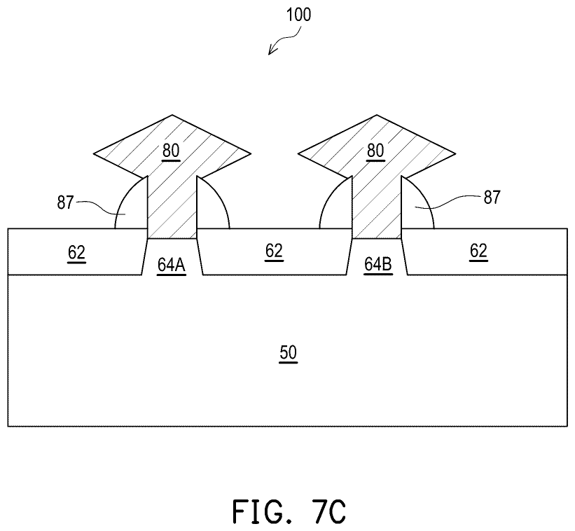

FIGS. 2-6, 7A-7C, 8-16 and 19 are cross-sectional views of a FinFET device 100 at various stages of fabrication, in accordance with an embodiment. The FinFET device 100 is similar to the FinFET 30 in FIG. 1, but with multiple fins and multiple gate structures. FIGS. 2-5 illustrate cross-sectional views of the FinFET device 100 along cross-section B-B. FIGS. 6, 7A, 8-16, and 19 illustrate cross-sectional views of the FinFET device 100 along cross-section A-A. FIGS. 7B and 7C illustrate embodiment cross-sectional views of the FinFET device 100 along cross-section C-C.

FIG. 2 illustrates a cross-sectional view of the substrate 50. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

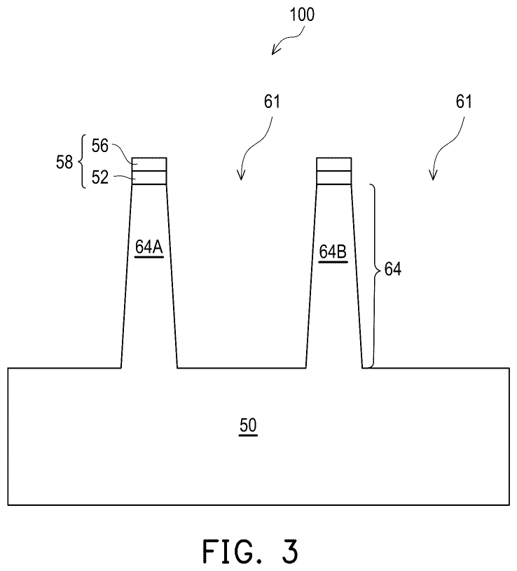

Referring to FIG. 3, the substrate 50 shown in FIG. 2 is patterned using, for example, photolithography and etching techniques. For example, a mask layer 58, such as a pad oxide layer 52 and an overlying pad nitride layer 56, is formed over the substrate 50. The pad oxide layer 52 may be a thin film comprising silicon oxide formed, for example, using a thermal oxidation process. The pad oxide layer 52 may act as an adhesion layer between the substrate 50 and the overlying pad nitride layer 56. In some embodiments, the pad nitride layer 56 is formed of silicon nitride, silicon oxynitride, silicon carbonitride, the like, or a combination thereof, and may be formed using low-pressure chemical vapor deposition (LPCVD) or plasma enhanced chemical vapor deposition (PECVD), as examples.

The mask layer 58 may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer 58 in this example, from subsequent processing steps, such as etching. In this example, the photoresist material is used to pattern the pad oxide layer 52 and pad nitride layer 56 to form a patterned mask 58, as illustrated in FIG. 3.

The patterned mask 58 is subsequently used to pattern exposed portions of the substrate 50 to form trenches 61, thereby defining semiconductor fins 64 (e.g., 64A and 64B) between adjacent trenches 61. In some embodiments, the semiconductor fins 64 are formed by etching trenches in the substrate 50 using, for example, reactive ion etch (RIE), neutral beam etch (NBE), the like, or a combination thereof. The etching process may be anisotropic. In some embodiments, the trenches 61 may be strips (viewed from the top) parallel to each other, and closely spaced with respect to each other. In some embodiments, the trenches 61 may be continuous and surround the semiconductor fins 64. The semiconductor fins 64 may also be referred to as fins 64 hereinafter.

The fins 64 may be patterned by any suitable method. For example, the fins 64 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

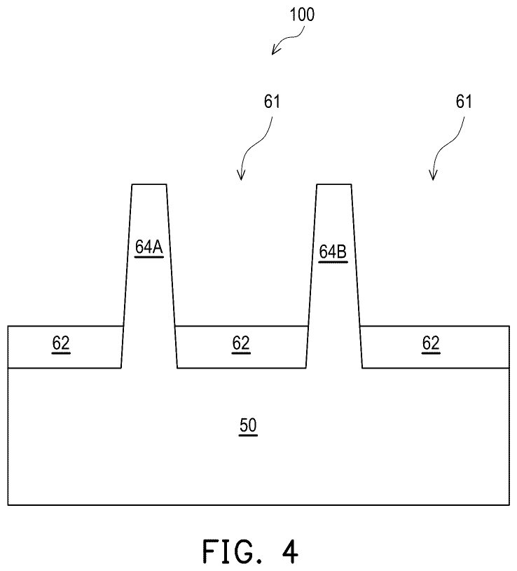

FIG. 4 illustrates the formation of an insulation material between neighboring semiconductor fins 64 to form isolation regions 62. The insulation material may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials and/or other formation processes may be used. In the illustrated embodiment, the insulation material is silicon oxide formed by a FCVD process. An anneal process may be performed once the insulation material is formed. A planarization process, such as a chemical mechanical polish (CMP), may remove any excess insulation material and form top surfaces of the isolation regions 62 and top surfaces of the semiconductor fins 64 that are coplanar (not shown). The patterned mask 58 (see FIG. 3) may also be removed by the planarization process.

In some embodiments, the isolation regions 62 include a liner (not specifically illustrated), e.g., a liner oxide, at the interface between the isolation region 62 and the substrate 50/semiconductor fins 64. In some embodiments, the liner oxide is formed to reduce crystalline defects at the interface between the substrate 50 and the isolation region 62. Similarly, the liner oxide may also be used to reduce crystalline defects at the interface between the semiconductor fins 64 and the isolation region 62. The liner oxide (e.g., silicon oxide) may be a thermal oxide formed through a thermal oxidation of a surface layer of substrate 50, although other suitable method may also be used to form the liner oxide.

Next, the isolation regions 62 are recessed to form shallow trench isolation (STI) regions 62. The isolation regions 62 are recessed such that the upper portions of the semiconductor fins 64 protrude from between neighboring STI regions 62. The top surfaces of the STI regions 62 may have a flat surface (as illustrated), a convex surface, a concave surface (such as dishing), or a combination thereof. The top surfaces of the STI regions 62 may be formed flat, convex, and/or concave by an appropriate etch. The isolation regions 62 may be recessed using an acceptable etching process, such as one that is selective to the material of the isolation regions 62. For example, a dry etch, or a wet etch using dilute hydrofluoric (dHF) acid, may be performed to recess the isolation regions 62.

FIGS. 2 through 4 illustrate an embodiment of forming fins 64, but fins may be formed in various different processes. For example, a top portion of the substrate 50 may be replaced by a suitable material, such as an epitaxial material suitable for an intended type (e.g., n-type or p-type) of semiconductor devices to be formed. Thereafter, the substrate 50, with epitaxial material on top, is patterned to form semiconductor fins 64 that comprise the epitaxial material.

As another example, a dielectric layer can be formed over a top surface of a substrate; trenches can be etched through the dielectric layer; homoepitaxial structures can be epitaxially grown in the trenches; and the dielectric layer can be recessed such that the homoepitaxial structures protrude from the dielectric layer to form fins.

In yet another example, a dielectric layer can be formed over a top surface of a substrate; trenches can be etched through the dielectric layer; heteroepitaxial structures can be epitaxially grown in the trenches using a material different from the substrate; and the dielectric layer can be recessed such that the heteroepitaxial structures protrude from the dielectric layer to form fins.

In embodiments where epitaxial material(s) or epitaxial structures (e.g., the heteroepitaxial structures or the homoepitaxial structures) are grown, the grown material(s) or structures may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fins 64 may comprise silicon germanium (SiₓGe₁₋ₓ, where x can be between 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

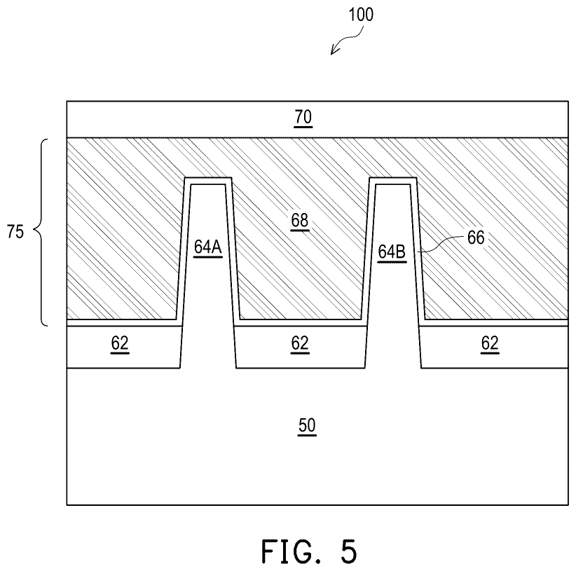

FIG. 5 illustrates the formation of gate structure 75 over the semiconductor fins 64. In accordance with various embodiments, the gate structure 75 is a dummy gate structure and includes a gate dielectric 66 and a gate electrode 68. A mask 70 may be formed over the dummy gate structure 75. To form the dummy gate structure 75, a dielectric layer is formed on the semiconductor fins 64. The dielectric layer may be, for example, silicon oxide, silicon nitride, multilayers thereof, or the like, and may be deposited or thermally grown.

A gate layer is formed over the dielectric layer, and a mask layer is formed over the gate layer. The gate layer may be deposited over the dielectric layer and then planarized, such as by a CMP. The mask layer may be deposited over the gate layer. The gate layer may be formed of, for example, polysilicon, although other materials may also be used. The mask layer may be formed of, for example, silicon nitride or the like.

After those layers (e.g., the dielectric layer, the gate layer, and the mask layer) are formed, the mask layer may be patterned using acceptable photolithography and etching techniques to form mask 70. The pattern of the mask 70 then may be transferred to the gate layer and the dielectric layer by an acceptable etching technique to form gate electrode 68 and gate dielectric 66, respectively. The gate electrode 68 and the gate dielectric 66 cover respective channel regions of the semiconductor fins 64. The gate electrode 68 may also have a lengthwise direction substantially perpendicular to the lengthwise direction of respective semiconductor fins 64.

The gate dielectric 66 is shown to be formed over the fins 64 (e.g., over top surfaces and sidewalls of the fins 64) and over the STI regions 62 in the example of FIG. 5. In other embodiments, the gate dielectric 66 may be formed by, e.g., thermal oxidization of a material of the fins 64, and therefore, may be formed over the fins 64 but not over the STI regions 62. These and other variations are fully intended to be included within the scope of the present disclosure.

FIGS. 6, 7A, 8-16, and 19 illustrate cross-sectional views of further processing of the FinFET device 100 along cross-section A-A (e.g., along a longitudinal axis of the fin 64). Note that in FIGS. 6, 7A, and 8, three dummy gate structures 75 (e.g., 75A, 75B, and 75C) are formed over the fin 64. One skilled in the art will appreciate that more or less than three gate structures 75 may be formed over the fin 64, these and other variations are fully intended to be included within the scope of the present disclosure.

FIG. 6 illustrates forming lightly doped drain (LDD) regions 65 in the fins 64. The LDD regions 65 may be formed by a plasma doping process. The plasma doping process may include forming and patterning masks such as a photoresist to cover the regions of the FinFET that are to be protected from the plasma doping process. The plasma doping process may implant n-type or p-type impurities in the fins 64 to form the LDD regions 65. For example, p-type impurities, such as boron, may be implanted in the fin 64 to form the LDD regions 65 for a p-type device. As another example, n-type impurities, such as phosphorus, may be implanted in the fin 64 to form the LDD regions 65 for an n-type device. In some embodiments, the LDD regions 65 abut the channel region of the FinFET device 100. Portions of the LDD regions 65 may extend under gate electrode 68 and into the channel region of the FinFET device 100. Note that other configurations, shapes, and formation methods of the LDD regions 65 are also possible and are fully intended to be included within the scope of the present disclosure. For example, LDD regions 65 may be formed after gate spacers 87 are formed. In some embodiments, the LDD regions 65 are omitted. For simplicity, the LDD regions 65 are not illustrated in subsequent figures, with the understanding the LDD regions 65 may be formed in the fin 64.

Still referring to FIG. 6, after the LDD regions 65 are formed, gate spacers 87 are formed around the dummy gate structures 75. The gate spacer 87 may include a first gate spacer 72 and a second gate spacer 86. Note that the gate spacer 87 may be considered part of the gate structure 75. For example, the first gate spacer 72 may be a gate seal spacer and is formed on opposing sidewalls of the gate electrode 68 and on opposing sidewalls of the gate dielectric 66. The second gate spacer 86 is formed on the first gate spacer 72. The first gate spacer 72 may be formed of a nitride, such as silicon nitride, silicon oxynitride, silicon carbonitride, the like, or a combination thereof, and may be formed using, e.g., a thermal oxidation, CVD, or other suitable deposition process. The second gate spacer 86 may be formed of silicon nitride, silicon carbonitride, a combination thereof, or the like using a suitable deposition method. In an embodiment, the first gate spacer 72 is formed of silicon nitride, and an atomic ratio between silicon and nitride (e.g., a ratio between the atomic percentages of silicon and nitride) is between about 0.7 and about 1.3.

In an embodiment, the gate spacer 87 is formed by first conformally depositing a first gate spacer layer over the FinFET device 100, then conformally depositing a second gate spacer layer over the deposited first gate spacer layer. Next, an anisotropic etch process, such as a dry etch process, is performed to remove a first portion of the second gate spacer layer disposed on upper surfaces of the FinFET device 100 (e.g., the upper surface of the mask 70) while keeping a second portion of the second gate spacer layer disposed along sidewalls of the gate structures 75. The second portion of the second gate spacer layer remaining after the anisotropic etch process forms the second gate spacer 86. The anisotropic etch process also removes a portion of the first gate spacer layer disposed outside of the sidewalls of the second gate spacer 86, and the remaining portion of the first gate spacer layer forms the first gate spacer 72.

The shapes and formation methods of the gate spacer 87 as illustrated in FIG. 6 are merely non-limiting examples, and other shapes and formation methods are possible. These and other variations are fully intended to be included within the scope of the present disclosure.

In FIG. 7A, recesses are formed in the fins 64 adjacent to the dummy gate structures 75, e.g., between adjacent dummy gate structures 75 and/or next to a dummy gate structure 75. Source/drain regions 80 are then formed in the recesses. The recesses are formed by, e.g., an anisotropic etching process using the dummy gate structures 75 and the gate spacers 87 as an etching mask, in some embodiments, although any other suitable etching process may also be used.

Next, the source/drain regions 80 are formed in the recesses. The source/drain regions 80 are formed by epitaxially growing a material in the recesses, using suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

As illustrated, the epitaxial source/drain regions 80 may have surfaces raised from respective surfaces of the fins 64 (e.g., raised above the non-recessed upper surface 64U of the fins 64) and may have facets. The source/drain regions 80 of the adjacent fins 64 may merge to form a continuous epitaxial source/drain region 80 (see FIG. 7B). In some embodiments, the source/drain regions 80 of the adjacent fins 64 do not merge together and remain separate source/drain regions 80 (see FIG. 7C). In some embodiments, the resulting FinFET is an n-type FinFET, and source/drain regions 80 comprise silicon carbide (SiC), silicon phosphorous (SiP), phosphorous-doped silicon carbon (SiCP), or the like. In some embodiments, the resulting FinFET is a p-type FinFET, and source/drain regions 80 comprise SiGe, and a p-type impurity such as boron or indium.

The epitaxial source/drain regions 80 may be implanted with dopants to form source/drain regions 80 followed by an anneal process. The implanting process may include forming and patterning masks such as a photoresist to cover the regions of the FinFET device 100 that are to be protected from the implanting process. The source/drain regions 80 may have an impurity (e.g., dopant) concentration in a range from about 1E19 cm⁻³ to about 1E21 cm⁻³. The p-type impurities, such as boron or indium, may be implanted in the source/drain region 80 of a p-type transistor. The n-type impurities, such as phosphorous or arsenide, may be implanted in the source/drain regions 80 of an n-type transistor. In some embodiments, the epitaxial source/drain regions 80 may be in situ doped during growth.

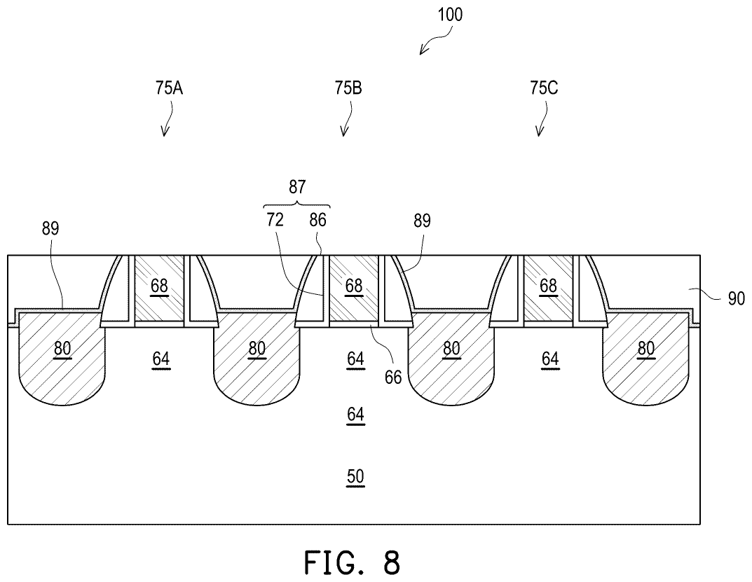

In FIG. 8, a contact etch stop layer (CESL) 89 is formed over the structure illustrated in FIG. 7A. The CESL 89 functions as an etch stop layer in a subsequent etching process, and may comprise a suitable material such as silicon oxide, silicon nitride, silicon oxynitride, combinations thereof, or the like, and may be formed by a suitable formation method such as CVD, PVD, combinations thereof, or the like.

Next, a first interlayer dielectric (ILD) 90 is formed over the CESL 89 and over the dummy gate structures 75 (e.g., 75A, 75B, and 75C). In some embodiments, the first ILD 90 is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. A planarization process, such as CMP, may be performed to remove the mask 70 (if present) and to remove portions of the CESL 89 disposed over the gate electrode 68. After the planarization process, the top surface of the first ILD 90 is level with the top surface of the gate electrode 68.

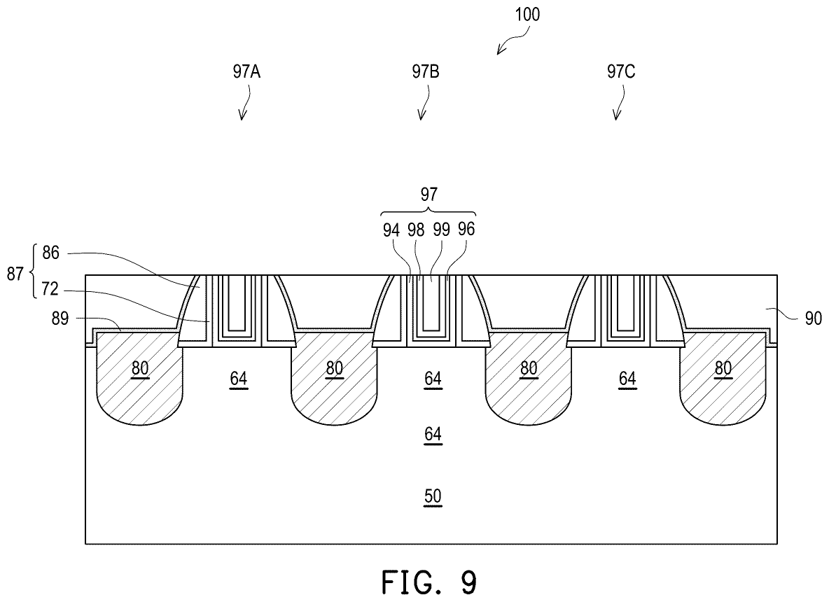

In FIG. 9, a gate-last process (e.g., a replacement gate process) is performed to replace the gate electrode 68 and the gate dielectric 66 (e.g., the dummy gate structure 75) with an active gate (e.g., a replacement gate or a metal gate) and active gate dielectric material(s), respectively. Therefore, the gate electrode 68 and the gate dielectric 66 may be referred to as a dummy gate electrode and a dummy gate dielectric, respectively, in a gate-last process.

As illustrated, the dummy gate structures 75A, 75B, and 75C are replaced by replacement gate structures 97A, 97B, and 97C, respectively. The replacement gate structures 97 (e.g., 97A, 97B, and 97C) may also be referred to as metal gate structures. In accordance with some embodiments, to form the replacement gate structures 97 (e.g., 97A, 97B, or 97C), the gate electrode 68 and the gate dielectric 66 directly under the gate electrode 68 are removed in an etching step(s), so that recesses (not shown) are formed between the gate spacers 87. Each recess exposes the channel region of a respective fin 64. During the dummy gate removal, the gate dielectric 66 may be used as an etch stop layer when the gate electrode 68 is etched. The gate dielectric 66 may then be removed after the removal of the gate electrode 68.

Next, a gate dielectric layer 94, a barrier layer 96, a work function layer 98, and a gate electrode 99 are formed in the recesses for the replacement gate structures 97. The gate dielectric layer 94 is deposited conformally in the recesses, such as on the top surfaces and the sidewalls of the fins 64 and on sidewalls of the gate spacers 87, and on a top surface of the first ILD 90 (not shown). In accordance with some embodiments, the gate dielectric layer 94 comprises silicon oxide, silicon nitride, or multilayers thereof. In some embodiments, the gate dielectric layer 94 includes a high-k dielectric material, and in these embodiments, the gate dielectric layers 94 may have a k-value greater than about 7.0, and may include a metal oxide or a silicate of Hf, Al, Zr, La, Mg, Ba, Ti, Pb, or combinations thereof. The formation methods of gate dielectric layer 94 may include molecular beam deposition (MBD), atomic layer deposition (ALD), PECVD, and the like.

The barrier layer 96 is formed conformally over the gate dielectric layer 94. The barrier layer 96 may comprise an electrically conductive material such as titanium nitride, although other materials, such as tantalum nitride, titanium, tantalum, or the like, may alternatively be utilized. The barrier layer 96 may be formed using a CVD process, such as PECVD. However, other alternative processes, such as sputtering, metal organic chemical vapor deposition (MOCVD), or ALD, may alternatively be used.

The work function layer 98, such as a p-type work function layer or an N-type work function layer, may be formed in the recesses over the barrier layer 96 and before the gate electrode 99 is formed, in accordance with some embodiments.

Exemplary p-type work function metals that may be included in the gate structures for p-type devices include TiN, TaN, Ru, Mo, Al, WN, ZrSi₂, MoSi₂, TaSi₂, NiSi₂, WN, other suitable p-type work function materials, or combinations thereof. Exemplary n-type work function metals that may be included in the gate structures for n-type devices include Ti, Ag, TaAl, TaAIC, TiAlN, TaC, TaCN, TaSiN, Mn, Zr, other suitable n-type work function materials, or combinations thereof. A work function value is associated with the material composition of the work function layer, and thus, the material of the work function layer is chosen to tune its work function value so that a desired threshold voltage Vt is achieved in the device that is to be formed. The work function layer(s) may be deposited by CVD, physical vapor deposition (PVD), and/or other suitable process.

In some embodiments, a seed layer (not shown) is formed conformally over the work function layer 98. The seed layer may include copper, titanium, tantalum, titanium nitride, tantalum nitride, the like, or a combination thereof, and may be deposited by ALD, sputtering, PVD, or the like. The seed layer is a metal layer, which may be a single layer or a composite layer comprising a plurality of sub-layers formed of different materials. For example, the seed layer comprises a titanium layer and a copper layer over the titanium layer.

The gate electrode 99 is then deposited over the seed layer, and fills the remaining portions of the recesses. The gate electrode 99 may be made of a metal-containing material such as Cu, Al, W, the like, combinations thereof, or multi-layers thereof, and may be formed by, e.g., electroplating, electroless plating, or other suitable method. After the formation of the gate electrode 99, a planarization process, such as a CMP, may be performed to remove the excess portions of the gate dielectric layer 94, the barrier layer 96, the work function layer 98, the seed layer, and the gate electrode 99, which excess portions are over the top surface of the first ILD 90. The resulting remaining portions of the gate dielectric layer 94, the barrier layer 96, the work function layer 98, the seed layer, and the gate electrode 99 thus form the replacement gate structure 97 of the resulting FinFET device 100.

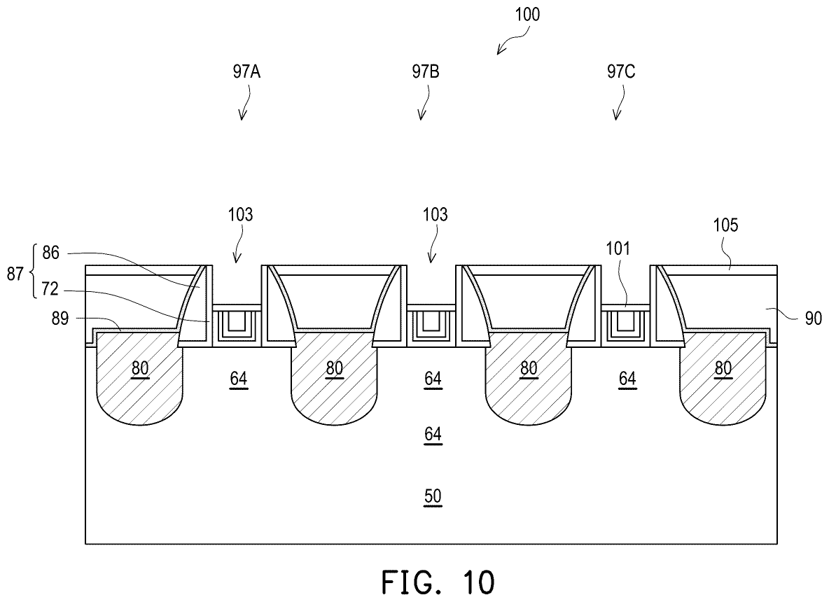

In FIG. 10, an etch stop layer 105 is formed (e.g., selectively) on the upper surface of the first ILD 90. The etch stop layer 105 may be a suitable dielectric material, such as silicon nitride or silicon oxynitride formed on the upper surface of the first ILD 90 by, e.g., CVD, ALD, combinations thereof, or the like. For example, a patterned mask layer may be formed to cover the replacement gate structures 97 and the gate spacers 87 while exposing the first ILD 90, and the etch stop layer 105 is then formed over the exposed first ILD 90. After the etch stop layer 105 is formed, the patterned mask layer is removed. As another example, an upper layer of the first ILD 90 may be converted into the etch stop layer 105, e.g., by a nitridation process using a nitride-containing gas or a nitride-containing plasma.

Next, the replacement gate structures 97 are recessed to form recesses 103 between respective gate spacers 87. In some embodiments, a metal gate etch-back process is performed to remove upper portions of the replacement gate structures 97, and as a result, recesses 103 are formed between the gate spacers 87 after the metal gate etch-back process. A suitable etching process, such as dry etch, wet etch, or combinations thereof, may be performed as the metal gate etch-back process.

Still referring to FIG. 10, after the recesses 103 are formed, a capping layer 101 is formed on the recessed replacement gate structures 97. In some embodiments, the capping layer 101 is formed of an electrically conductive material, such as tungsten, using a suitable deposition method, such as ALD, CVD, PVD, or the like. In the example of FIG. 10, the capping layer 101 extends continuously along the upper surface of the replacement gate structure 97 from an inner sidewall of a gate spacer 87 to an opposing inner sidewall of a respective gate spacer 87. In other words, the capping layer 101 completely covers the upper surface of the replacement gate structures 97, in the illustrated embodiment. In some embodiments, the capping layer 101 is omitted.

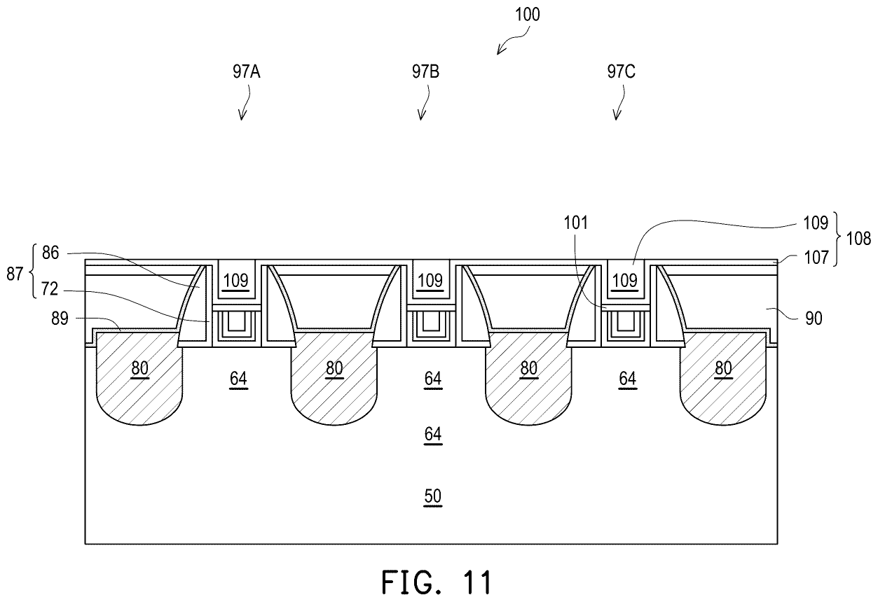

In FIG. 11, the recesses 103 are filled by a mask structure 108. As illustrated, a semiconductor material 107 (also referred to as a semiconductor liner) is formed conformally along sidewalls and bottoms of the recesses 103, and along the upper surface of the etch stop layer 105. Next, a dielectric material 109 is formed over the semiconductor material 107 to fill the recesses 103. The dielectric material 109 may also be formed outside the recesses 103 over portions of the semiconductor material 107 between replacement gate structures 97. The semiconductor material 107 and the dielectric material 109 are collectively referred to as a mask structure 108.

In an example embodiment, the semiconductor material 107 is amorphous silicon (a-Si) formed by a suitable deposition process such as LPCVD, PECVD, ALD, or the like, using a silicon-containing process gas such as SiH₄, Si₂H₆, SiH₂ Cl₂, combinations thereof, or the like. In some embodiments, a treatment process may be performed to amorphize any polycrystalline structures that may have formed in the semiconductor material 107. In the discussion herein, the conformal semiconductor material 107 may also be referred to as a silicon liner, with the understanding that other suitable material may also be used as the semiconductor material 107.

In addition, the dielectric material 109 may be silicon nitride formed by a suitable formation method, such as ALD, PECVD, LPCVD, or the like. Besides silicon nitride (e.g., SiN), other suitable dielectric material, such as silicon carbon nitride (SiCN), silicon carbon oxynitride (SiCON), and silicon carbon oxide (SiCO), may also be used as the dielectric material 109. In some embodiments, the dielectric material 109 is chosen to be different from the material(s) of the gate spacers 87 to provide etching selectivity in subsequent etching processes.

Still referring to FIG. 11, a planarization process, such as CMP, is performed to remove excess portions of the semiconductor material 107 and excess portions of the dielectric material 109, which excess portions are over the upper surface of the first ILD 90. As illustrated, the planarization process may also remove the etch stop layer 105 and top portions of the gate spacers 87. After the planarization process, the remaining portions of the semiconductor material 107 and the dielectric material 109 disposed between (remaining portions of) respective gate spacers 87 are referred to as mask structures 108.

In FIG. 12, a second ILD 111 is formed over the first ILD 90, the gate spacers 87, and the mask structures 108. The second ILD 111 may be formed of a same or similar material using a same or similar formation method as the first ILD 90, thus details are not repeated. In some embodiments, the second ILD 111 is formed similarly as described above in connection with the first ILD 90. For example, the second ILD 111 may be a dielectric material such as silicon oxide, PSG, BSG, BPSG, USG, or the like, and may be deposited by any suitable method, such as CVD, PECVD, or FCVD. The second ILD 111 may serve as an etch stop layer over the gate structures 97 (e.g., over the mask structures 108) in a subsequent etching process.

As illustrated, an etch stop layer stack 112 is formed over the second ILD 111 and patterned to have openings 120 in the etch stop layer stack 112. In some embodiments, the etch stop layer stack 112 includes a plurality of layers (also referred to as sublayers), where each of the plurality of layers is formed of a different material. In the illustrated example, the etch stop layer stack 112 includes a first layer 113, a second layer 115, and a third layer 117 formed successively over the second ILD 111. The first layer 113 is formed of tungsten doped carbide (WDC, also known as tungsten doped silicon carbide), the second layer 115 is formed of an oxide (e.g., silicon oxide), and the third layer 117 is formed of silicon (e.g. Si). The different materials of the sublayers of the etch stop layer stack 112 combine to provide a target level of etching selectivity for, e.g., a subsequent etching process.

Next, the etch stop layer stack 112 is patterned to form the openings 120 in the etch stop layer stack 112. For example, a patterned mask layer 119 (e.g., a patterned photoresist layer) is formed over the etch stop layer stack 112, and an anisotropic etching process is then performed using the patterned mask layer 119 as an etching mask to pattern the patterned mask layer 119. The illustrated number and the location of the openings 120 provide a non-limiting example. One skilled in the art will readily appreciate that other numbers of openings 120 may be formed at other locations. In some embodiments, the anisotropic etching process includes a plurality of etching steps, where each of the etching steps uses a different etchant to selectively remove a sublayer of the etch stop layer stack 112. The anisotropic etching process may stop when the second ILD 111 is exposed.

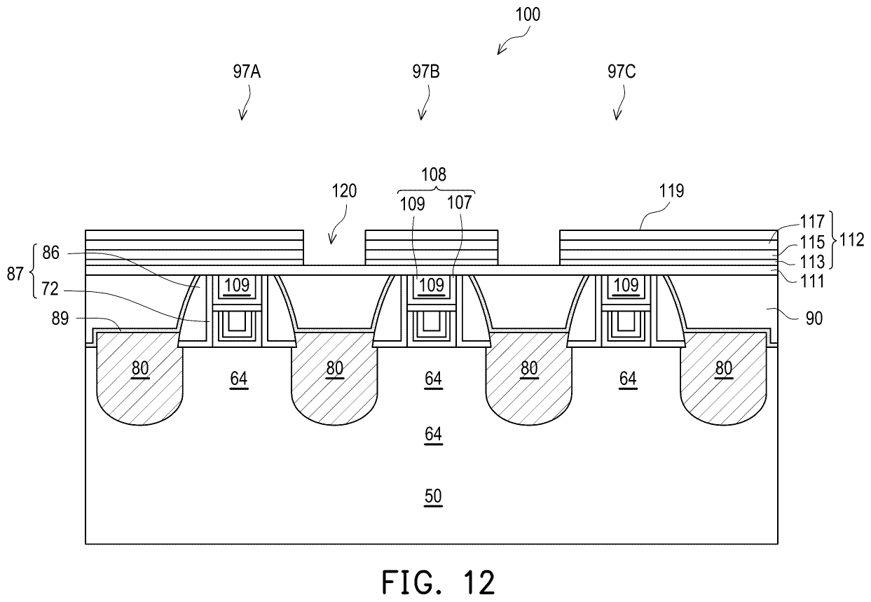

Next, in FIG. 13, an etching process is performed to remove portions of the second ILD 111 and portions of the first ILD 90 underlying the opening 120. Optionally, the patterned mask layer 119 (e.g., a patterned photoresist layer) may first be removed, e.g., by an ashing process. In accordance with various embodiments, the etching process is used to extend the openings 120 such that openings 121 are formed in the first ILD 90 which expose the underlying source/drain regions 80. The etching process may be any suitable etching process, such as a dry etch (e.g., a plasma etching process), a wet etch, combinations thereof, or the like. The etching process may use an etchant that is selective to (e.g., having a higher etching rate for) the material (e.g., oxide) of the first ILD 90 and the second ILD 111, such that the first ILD 90 and the second ILD 111 are removed without substantially attacking other layers of the FinFET device 100. For example, an etching processing using CₓF_{y}, H₂, Ar, combinations thereof, or the like may be performed to remove the exposed portions of the first ILD 90 and the second ILD 111. In some embodiments, after the etching process to remove the exposed portions of the first ILD 90 and the second ILD 111, another etching process using an etchant selective to the material of the CESL 89 is performed to remove the CESL 89 exposed by the openings 121 and to expose the source/drain regions 80.

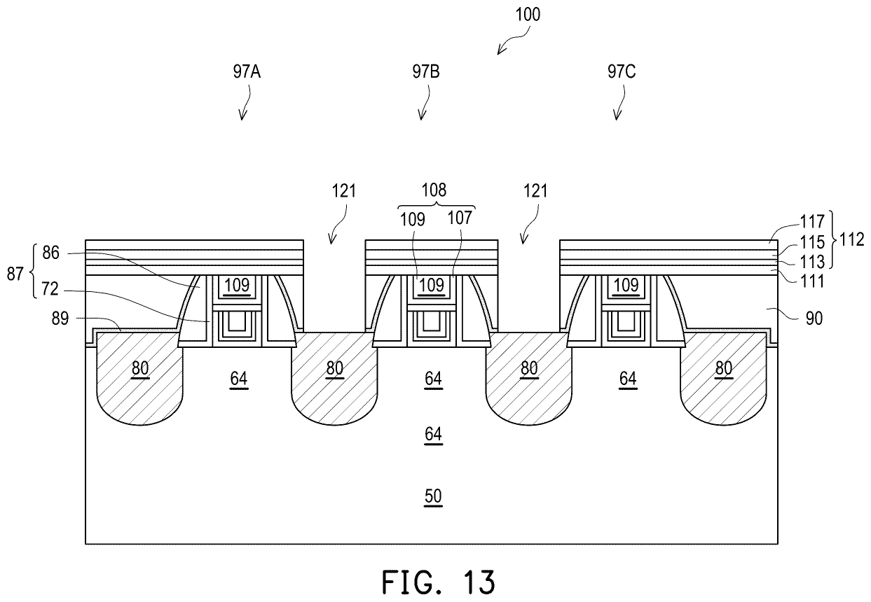

Next, in FIG. 14, a conductive material 122 is formed in the openings 121 to fill the openings 121 at least above the second ILD 111. The conductive material 122 may be ruthenium, copper, cobalt, tungsten, molybdenum, iridium, combinations thereof, or the like, and may be formed by a suitable formation method such as PVD, CVD, PECVD, ALD, or the like. In some embodiments (not specifically illustrated), a barrier layer may be conformally deposited before depositing the material(s) listed above. For example, the barrier layer may be a metal nitride, such as tantalum nitride, titanium nitride, or the like and formed by, e.g., PVD, ALD, or any suitable method. In various embodiments, the conductive material 122 includes ruthenium and may or may not include an underlying barrier layer of tantalum nitride.

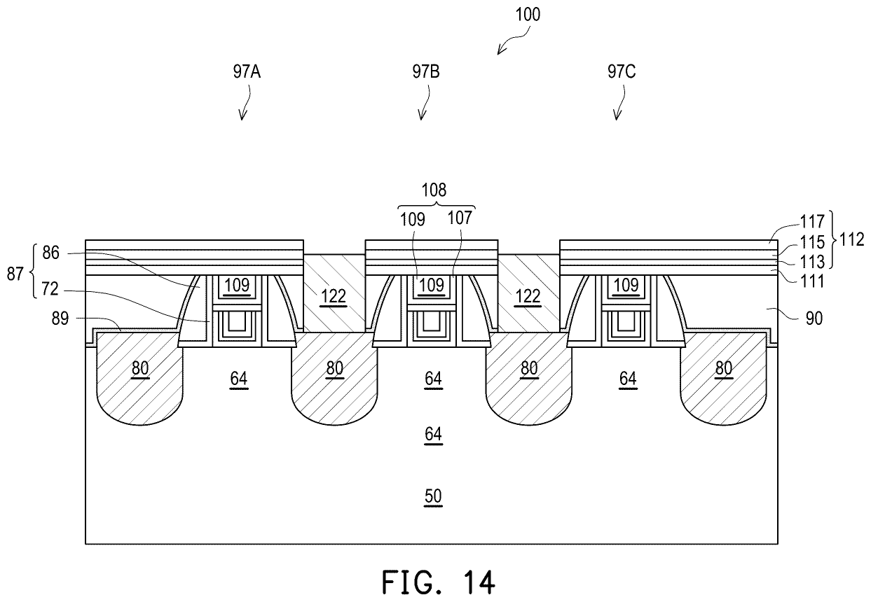

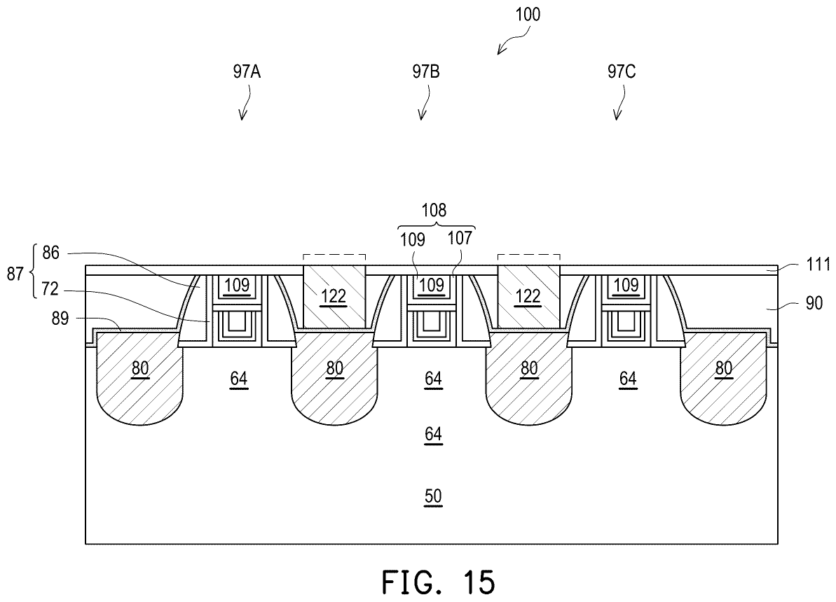

In FIG. 15, a first removal process is performed to remove the etch stop layer stack 112 and any portions of the conductive material 122 that may protrude above the second ILD 111. In some embodiments, the first removal process includes a first CMP process. The first CMP process may be a bulk CMP process in order to remove the conductive material 122 and the etch stop layer stack 112 at a high polishing rate. Planarizing the structure to remove the etch stop layer stack 112 quickly may outweigh requirements for a high degree of planarity, which will be addressed in subsequent steps discussed below.

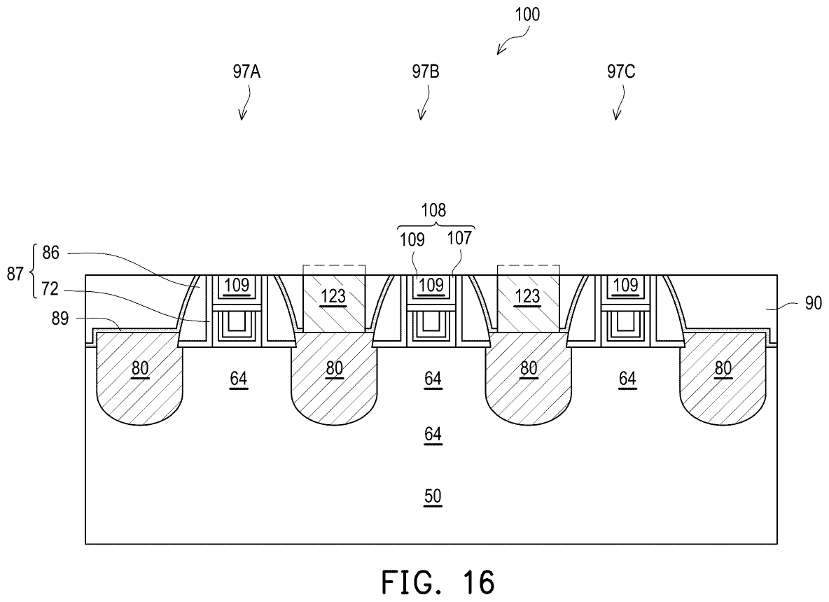

In FIG. 16, a second removal process is performed to remove the second ILD 111 and portions of the conductive material 122 that protrude above the first ILD 90. The remaining portions of the conductive material 122 in the openings 121 form contacts 123. As illustrated, after the planarization process, the first ILD 90, the mask structure 108, the gate spacers 87, and the contacts 123 have coplanar upper surfaces. In some embodiments, the second removal process includes a second CMP process. The second CMP process may be a buffing CMP process in order to remove the conductive material 122 and the second ILD 111 at a slower and even polishing rate (e.g., a low polishing rate).

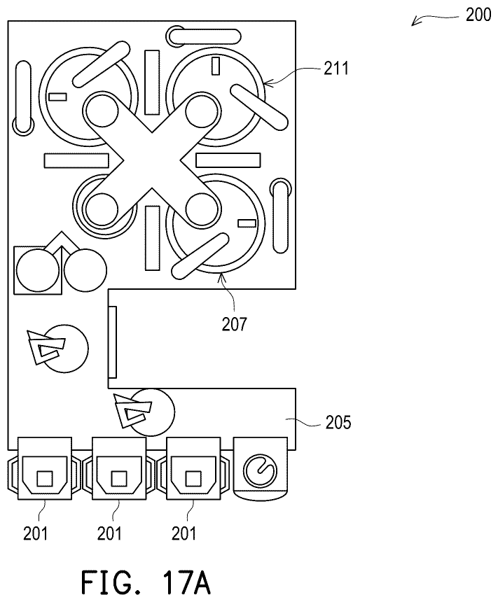

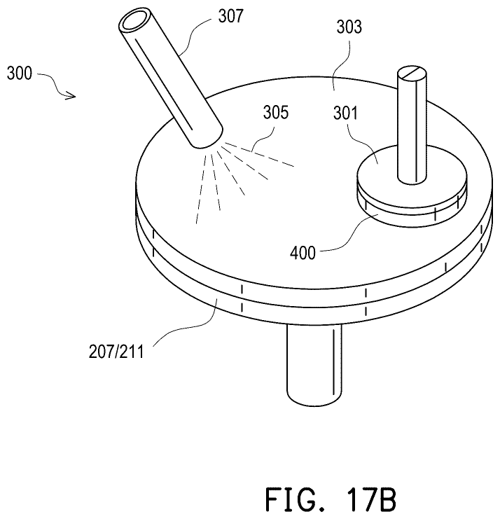

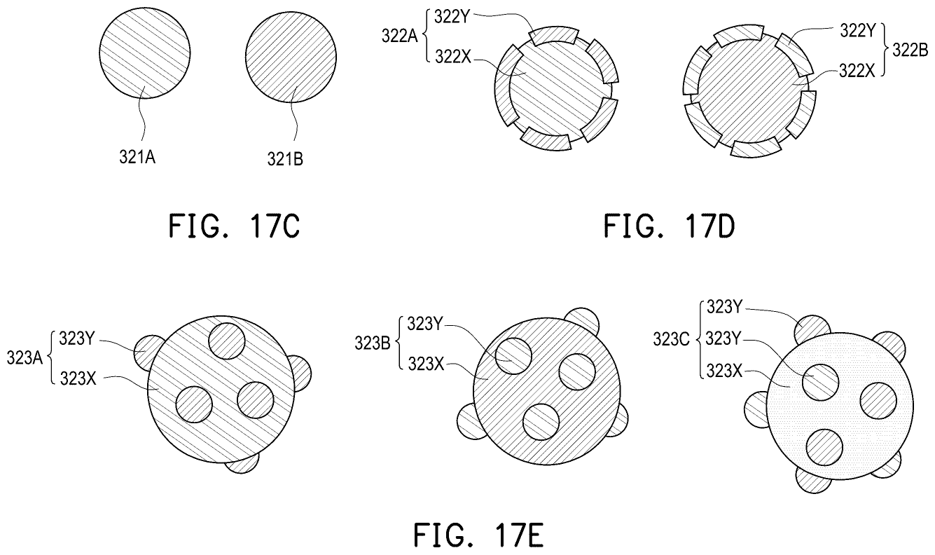

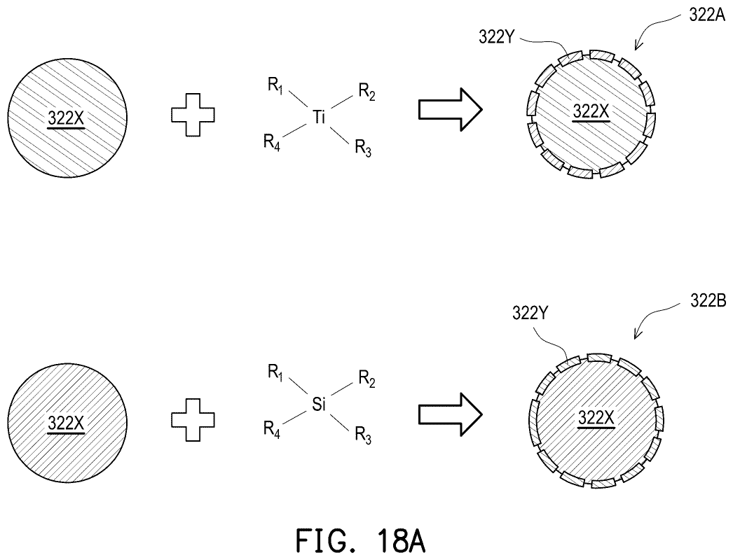

The first and second CMP processes utilize several additional process parameters as discussed in greater detail below (see FIGS. 17A-17E). In an embodiment, the first and second CMP processes may be performed continuously with similar process parameters, albeit with a decreasing polishing rate from the first CMP process to the second CMP process. In another embodiment, several other process parameters may also change.

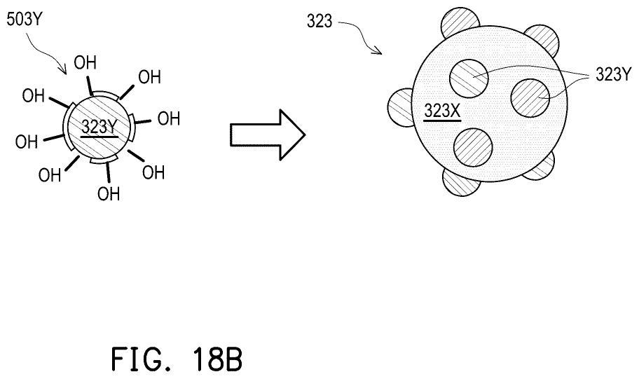

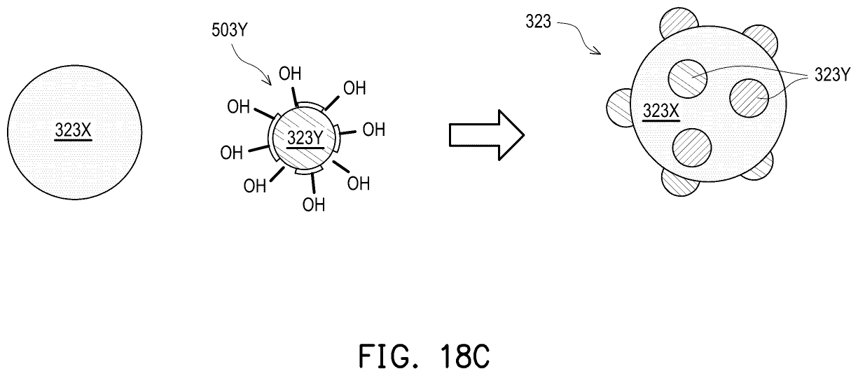

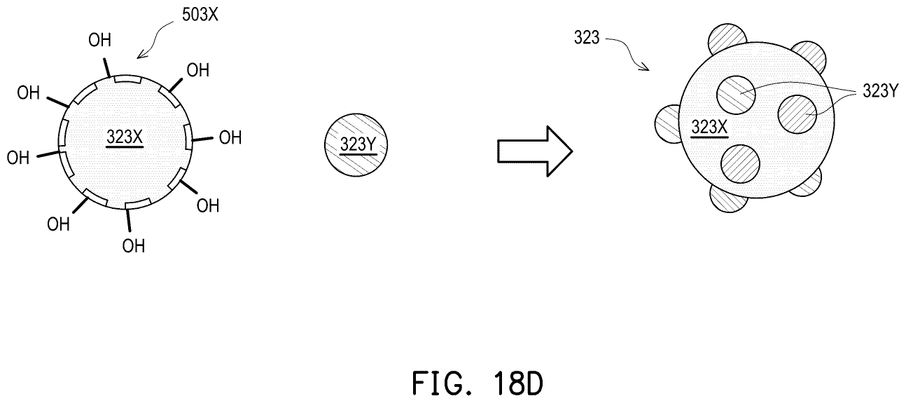

FIGS. 17A-18D illustrate process features relating to the second CMP process (see FIG. 16), which may also be applicable to the first CMP process (see FIG. 15). In particular, the figures illustrate an exemplary CMP system 200 and various types of abrasives 311 that may be included in a CMP slurry 305 to achieve several advantages. Although the CMP slurry 305 is generally described in relation to polishing ruthenium as the conductive material 122, it should be appreciated that embodiments of the CMP slurry 305 (e.g., the various types of abrasives 311 and other ingredients) may also apply to other conductive materials 122 such as tungsten, molybdenum, iridium, or the like.

FIGS. 17A and 17B illustrate a CMP system 200 which may be used to remove the excess conductive material 122 and to remove the excess materials of the second ILD 111, as discussed above in connection with FIGS. 15-16. Referring to FIG. 17A, the CMP system 200 may include loadlocks 201, a cleaning station 205, a high-rate platen 207, and a buffing platen 211. The loadlocks 201 may be used for loading the workpiece 400 (see FIG. 17B) into the CMP system 200, and then unloading the workpiece 400 once the CMP process has been completed. In some embodiments, the high-rate platen 207 may be used for the first CMP process (see FIG. 15) to polish and remove some portions of the conductive material 122 and the etch stop layer stack 112 with a relatively high polishing rate (e.g., a bulk polishing rate). In addition, the buffing platen 211 may be used in the second CMP process (see FIG. 16) to polish and remove additional portions of the conductive material 122 and the second ILD 111. The buffing platen 211 may also be used to fix defects and scratches that may occur during the removal of the conductive material 122.

In an embodiment, the workpiece 400 may be loaded into the CMP system 200 through the loadlocks 201 and passed to the high-rate platen 207 for a bulk removal of the conductive material 122 during, e.g., the first CMP process. Once at the high-rate platen 207, the workpiece 400 may be connected to a carrier 301 (see FIG. 17B), which faces the surface of the conductive material 122 (e.g., the outer surface of the workpiece 400) towards a polishing pad 303 connected to the high-rate platen 207.

FIG. 17B illustrates a CMP apparatus 300 of the CMP system 200. The CMP apparatus may generally apply to either the first CMP process (e.g., using a high-rate platen 207) and the second CMP process (e.g., using a buffing platen 211). The illustrated polishing pad 303 may be a hard polishing pad that may be utilized for a relatively quick removal of the conductive material 122, or the illustrated polishing pad 303 may be a soft buffing pad that may be utilized for a slower and more controlled removal of the conductive material 122 while also buffing and eliminating defects and scratches that may have been caused by the first CMP process. However, any other suitable polishing pads 303 may be used for each of the first and second CMP processes.

During the CMP processes, the carrier 301 may press the surface of the conductive material 122 against the polishing pad 303. The workpiece 400 and the polishing pad 303 are each rotated against each other, either in the same direction or else counter-rotated in opposite directions. By rotating the polishing pad 303 and the workpiece 400 against each other, the polishing pad 303 mechanically grinds away the conductive material 122 and the dielectric material (e.g., the etch stop layer stack 112 or the second ILD 111) for removal. Additionally, in some embodiments the carrier 301 may move the workpiece 400 back and forth along a radius of the polishing pad 303.

In accordance with various embodiments, the mechanical grinding of the polishing pad 303 is assisted through the use of a CMP slurry 305, which may be dispensed onto the polishing pad 303 through a slurry dispensing system 307. In various embodiments, the CMP slurry 305 comprises one or more types of abrasives and a reactant. In addition, the CMP slurry 305 may include one or more pH regulators (e.g., a pH adjustor and/or a pH buffer). Further, the CMP slurry 305 may include additives for protection of the conductive material 122 (e.g., corrosion inhibitor), for topographical control (e.g., dishing and erosion reduction), or the like, wherein the additives may include molecules, surfactants, and polymers.

The reactant in the CMP slurry 305 may be a chemical that will chemically react with the conductive material 122 in order to assist the polishing pad 303 in grinding away the conductive material 122. In some embodiments, the reactant may be an oxidizer. For example, the reactant may be a peroxide, such as hydrogen peroxide (H₂O₂), although any other suitable reactant (e.g., oxidizer), including other peroxides such as dicumyl peroxide, di-tetra-butyl peroxide, cumene hydroperoxide, the like, or combinations thereof, that will aid in the removal of the conductive material 122 may also be utilized. In some embodiments, a concentration of the oxidizer (e.g., H₂O₂) ranges from about 0.01% to about 10% by weight, such as about 1% to about 2% by weight.

In some embodiments, the CMP slurry 305 may include a surfactant utilized to help disperse the first reactant 313 and the abrasive 311 within the CMP slurry 305 and also prevent the abrasive 311 from agglomerating during the CMP process. For example, the surfactant may include sodium salts of polyacrylic acid, potassium oleate, sulfosuccinates, sulfosuccinate derivatives, sulfonated amines, sulfonated amides, sulfates of alcohols, alkylanyl sulfonates, carboxylated alcohols, alkylamino propionic acids, alkyliminodipropionic acids, combinations of these, or the like. However, these embodiments are not intended to be limited to these surfactants, as any suitable surfactant may be utilized.

As discussed above, the CMP slurry 305 includes one or more pH regulating agents (e.g., a pH adjustor and a pH buffer). The pH adjustor helps to bring the CMP slurry 305 to a desired pH (e.g., between pH 1 and pH 12), while the pH buffer (e.g., a pH buffering agent) helps to substantially maintain the CMP slurry 305 at the desired pH. In some embodiments, the pH regulators set and maintain the pH at a range of 4-9. It should be appreciated that a pH at or above 4 prevents or reduces production of toxic ruthenium oxide during the CMP process. Conversely, a pH at or below 9 ensures a sufficiently fast oxidation reaction rate of ruthenium during the CMP process.

For example, the pH adjustor may include acidic pH adjusting agent(s), such as hydrochloric acid, nitric acid, acetic acid, sulfuric acid, phosphoric acid, phthalic acid, the like, other inorganic or organic acids, and mixtures thereof. In addition, the pH adjustor may include basic pH adjusting agent(s), such as ammonium hydroxide, potassium hydroxide, sodium hydride, tetra-alkyl hydroxide (e.g., tetraethyl ammonium hydroxide or tetrabutyl ammonium hydroxide), organic amines, and other chemical reagents that are able to be used to adjust pH towards more alkaline direction. Note that any suitable combination of these pH adjustors may be utilized.

The pH buffer stabilizes the CMP slurry 305 at the desired pH range, whether for a pH ranging from 1-4, ranging from 4-9, or ranging from 9-12. For example, the pH buffer for a pH range of 1-4 may include carboxylic acids or the like. The pH buffer for a pH range of 4-9 may include bis-tris-methane, MES, PIPES, MOPS, 4-(2-hydroxyethyl)-1-piperazineethanesulfonic acid (HEPES), tricine (tris glycine), bicine, phosphates, N-[Tris(hydroxymethyl)methyl]-3-aminopropanesulfonic acid (TAPS), or the like. The pH buffer for a pH range of 9-12 may include amines, ammonium hydroxide, or the like. Note that any suitable pH buffer (or any suitable combination of pH regulators) may be utilized.

As discussed above, the CMP slurry 305 may comprise other additives. For example, the CMP slurry 305 may comprise a corrosion inhibitor (e.g., ruthenium corrosion protection). The corrosion inhibitor may include chemicals with functional groups that can interact with ruthenium to protect against chemical attacks. For example, the corrosion inhibitor may be a surfactant (as described above) as well as a polymer or other molecule with functional groups such as amino acids, amines, azoles, pyridines, imines, sulfonates, phosphates, or the like. In addition, the CMP slurry 305 may comprise chemicals for topographical control (e.g., dishing and erosion reduction). Similarly, the topographical control chemicals may be a surfactant or polymer, including non-ionic, anionic, and cationic types, such as polyacrylic acid, polyethylene glycol, polyethylenimine (PEI), alkyl sulfonate, alkyl ether phosphate, lauryl ether, lauryl amine, quaternary ammonium salts, or the like. However, any other suitable additives may be utilized.

The remainder of the CMP slurry 305 may be a solvent (e.g., a liquid carrier) that may be utilized to combine the first reactant 313, the abrasive 311, the surfactant, pH regulators, and other additives and to allow the mixture to be moved and dispersed onto the polishing pad 303. For example, the solvent of the CMP slurry 305 may be deionized water or an alcohol. However, any other suitable solvent may be utilized.

FIGS. 17C-17E illustrate exemplary types of the abrasives 311 which may be included in the CMP slurry 305. The abrasives 311 comprise particulates that, in conjunction with the polishing pad 303, aid in the removal of the conductive material 122 and corresponding dielectric material(s). In accordance with various embodiments, the abrasives 311 of the CMP slurry 305 include both titania (e.g., titanium oxide or TiO₂) and silica (e.g., silicon oxide or SiO₂). FIG. 17C illustrates the abrasives 311 having a simple structure (e.g., simple abrasives 321) such that the abrasives 311 include a mixture of silica abrasives 321A and titania abrasives 321B.

FIGS. 17D and 17E illustrate the abrasives 311 having at least hybrid structures. In particular, FIG. 17D illustrates the abrasives 311 having a core-shell structure (e.g., core-shell abrasives 322) such that the abrasives 311 include either or both of silica core abrasives 322A and titania core abrasives 322B. As shown, the core-shell abrasive 322 includes a core 322X (e.g., a core structure) and a shell 322Y (e.g., a shell structure). For example, the silica core abrasives 322A have a silica core 322X and a titania shell 322Y, while the titania core abrasives 322B have a titania core 322X and a silica shell 322Y. Further, FIG. 17E illustrates the abrasives 311 having a composite structure (e.g., composite abrasives 323) such that the abrasives 311 include one or more of silica carrier abrasives 323A, titania carrier abrasives 323B, or alternative carrier abrasives 323C. As shown, the composite abrasive 323 includes a core 323X (e.g., a carrier structure) with particulates 323Y sprinkling (e.g., decorating or adorning) an outer surface of the core 323X (e.g., a particulate structure). For example, the silica carrier abrasives 323A have a silica core 323X, the titania carrier abrasives 323B have a titania core 323X, and the alternative carrier abrasives 323C have a different material core 323X, wherein each of the types of composite abrasives 323 is sprinkled (e.g., decorated) by silica particulates 323Y and/or titania particulates 323Y.

Advantages are achieved by using a CMP slurry 305 containing abrasives 311 comprising both titania (e.g., TiO₂) and silica (e.g., SiO₂). In particular, a metal polish rate (e.g., removal rate) by titania abrasives increases in the presence of certain oxidizers (e.g., peroxides such as hydrogen peroxide). In embodiments in which the conductive material 122 comprises ruthenium, titania abrasives complemented by such an oxidizer (e.g., H₂O₂) may also prevent or reduce staining of the polishing pad 303, e.g., by ruthenium oxide formed during the CMP process. In addition, titania abrasives without the oxidizer (e.g., H₂O₂) have a high silicon oxide removal rate, while that silicon oxide removal rate decreases when the titania abrasives are in the presence of the oxidizer. However, the silicon oxide removal rate increases with titania abrasives and the oxidizer which are further complemented by silica abrasives. As such, titania and silica abrasives (e.g., the abrasives 311 comprising both titania material and silica material) can effectively polish ruthenium (Ru) using weak oxidizers (e.g., peroxides such as H₂O₂).

Furthermore, the disclosed embodiments achieve the additional advantages of preventing or reducing tool corrosion (e.g., equipment of the CMP system 200).

Additionally, the CMP by-products of using such weak oxidizers are safer for the environment as well as users of the CMP system 200 because certain weak oxidizers tend to react with ruthenium to produce non-toxic gases (e.g., ruthenium hydroxide (Ru(OH)₃) instead of toxic gases (e.g., ruthenium tetroxide (RuO₄)). As illustrated, the abrasives 311 may include combinations of titania and silica particles or particles that contain both titania and silica portions (or combinations thereof).

Referring again to FIG. 17C, the simple abrasives 321 may include a mixture of silica abrasives 321A and titania abrasives 321B. Each of the types of the simple abrasives 321 may have a particle size (e.g., diameter) ranging between about 10 nm and about 300 nm, such as 150 nm. In some embodiments, the proportion of the silica abrasives 321A to the titania abrasives 321B may be selected and adjusted to achieve desired specifications for the CMP process. For example, the silica abrasives 321A may be included at a greater, lesser, or substantially same quantity as the titania abrasives 321B. In addition, the particle sizes of the silica abrasives 321A and the titania abrasives 321B may be selected and adjusted. For example, the silica abrasives may have a greater, lesser, or substantially same particle size as the titania abrasives 321B. In some embodiments, the silica abrasives 321A may have a greater quantity with a lesser particle size as compared with the titania abrasives 321B, or vice versa. For example, the parameters may be selected in order for a total exposed surface area of the silica abrasives 321A to be greater, lesser, or substantially same as a total exposed surface area of the titania abrasives 321B. However, it should be appreciated that any suitable combination of the above described parameters may be utilized.

Referring again to FIG. 17D, the core-shell abrasives 322 may include one or both of silica core abrasives 322A and titania core abrasives 322B. For example, each of the core-shell abrasives 322 includes a core 322X (e.g., a core structure) and a shell 322Y (e.g., a shell structure). The silica core abrasives 322A have a silica core 322X and a titania shell 322Y, while the titania core abrasives 322B have a titania core 322X and a silica shell 322Y. In accordance with various embodiments, the shell 322Y is chemically bonded to the core 322X. The shell 322Y may cover a minority, a majority, or substantially all of an outer surface of the core 322X. In some embodiments, coverage of the shell 322Y may range from about 10% to about 90%. As discussed above, each of the abrasives 311 (e.g., the core-shell abrasives 322) may have a particle size of between about 10 nm and about 300 nm, such as 150 nm. For example, the core 322X may have a particle size of between about 10 nm and about 300 nm, while the shell 322Y may have a thickness of about 2-5 Å (e.g., a monolayer) to about 10 nm (e.g., having significantly less or substantially negligible effect on the overall particle size of the core-shell abrasives 322). In some embodiments, the shell 322Y may be a monolayer over the core 322X.

Similarly as described above in connection with the simple abrasives 321, various parameters of the silica core abrasives 322A and the titania core abrasives 322B may be selected and adjusted to achieve desired specifications for the CMP process. In addition to varying the quantities and the particles sizes of the core-shell abrasives 322, the coverage of the core 322X by the shell 322Y may be selected and adjusted to further achieve desired specifications. In some embodiments, shell coverage of the silica core abrasives 322A may be greater, lesser, or substantially same as the shell coverage of the titania core abrasives 322B. In embodiments in which the CMP slurry 305 utilizes only one type of the core-shell abrasives 322, the shell coverage may be selected to achieve a desired proportion of surface areas between the silica and titania materials. Moreover, any suitable combinations of simple abrasives 321 and core-shell abrasives 322 may be utilized. As such, the combinations of disclosed embodiments may be selected to achieve a desired proportion of surface areas between the silica and titania materials, and such proportion may range from about 10% to about 90%.

Referring again to FIG. 17E, the composite abrasives 323 may include one or more of silica carrier abrasives 323A, titania carrier abrasives 323B, or alternative carrier abrasives 323C. In the illustrated embodiments, the silica carrier abrasives 323A have a silica core 323X sprinkled by titania particulates 323Y, while the titania carrier abrasives 323B have a titania core 323X sprinkled by silica particulates 323Y. In addition, the alternative carrier abrasives 323C have an alternative material as the core 323X (e.g., instead of silica or titania) sprinkled by particulates 323Y which may include either or both of silica and titania particulates. In addition, the alternative material of the core 323X may include various metals, non-metals (e.g., including polymeric materials), or metal oxides, such as gold (Au), silver (Ag), aluminum oxide (Al₂O₃), zirconium oxide (ZrO₂), cesium oxide (CeO₂), zinc oxide (ZnO), or the like. Any suitable combinations of the composite abrasives 323 may be utilized in the CMP slurry 305.

As discussed above, each of the composite abrasives 323 may have a particle size of between about 10 nm and about 300 nm, such as 150 nm. For example, the core 323X may have a particle size of between about 30 nm and about 300 nm, while the particulates 323Y may have a particle size of between about 1 nm and about 30 nm (e.g., having significantly less or substantially negligible effect on the overall particle size of the composite abrasives 323). In accordance with various embodiments, the particulates 323Y are chemically bonded to the core 323X and may cover a minority or a majority of an outer surface of the core 322X. For example, coverage of the particulates 323Y may range from about 0.05% to about 50%, such as about 10% to about 50%.

Similarly as described above in connection with the simple abrasives 321 and the core-shell abrasives 322, various parameters of the composite abrasives 323 may be selected and adjusted to achieve desired specifications for the CMP process. In addition to varying the quantities and the particles sizes of the respective types of the composite abrasives 323, the coverage of the core 323X by the particulates 323Y may be selected and adjusted to further achieve desired specifications. Similarly as with previous embodiments, the particulate coverage may be selected to achieve a desired proportion of surface areas between the silica and titania materials. Parameters relating to the sizes of the core 323X and the particulates 323Y may also be selected and adjusted to achieve the desired proportion of surface areas. As noted above, any suitable combination and proportion of the exemplary composite abrasives 323 may be utilized. Moreover, any suitable combinations of simple abrasives 321, core-shell abrasives 322, and composite abrasives 323 may be utilized. As such, a desired proportion of surface areas between the silica and titania materials may range from about 10% to about 90%.

Furthermore, the first CMP process and the second CMP process may utilize differing combinations of embodiments of the abrasives 311. For example, the first CMP process (e.g., a bulk polishing process) may include larger particles than the second CMP process (e.g., a buffing process). In addition, the first CMP process may utilize simple abrasives 321, while the second CMP process utilizes hybrid abrasives (e.g., the core-shell abrasives 322 and/or the composite abrasives 323). Because the hybrid abrasives 322/323 include silica and titania materials in close proximity, the hybrid abrasives 322/323 may provide improved control, which may be more important during the second CMP process.

Referring generally to FIGS. 17A-17E, as noted above, embodiments of the CMP slurry 305 disclosed herein refer to any suitable combination of reactants, abrasives, surfactants, solvents, and/or corrosion inhibitors described above in connection with various embodiments. Once mixed, the CMP slurry 305 may be dispensed onto the polishing pad 303 by the slurry dispensing system 307. In some embodiments, the workpiece 400 may be forced into contact with the polishing pad 303 by the carrier 301 pressing the surface of the workpiece 400 against the polishing pad 303. As the high-rate platen 207 rotates the polishing pad 303 underneath the workpiece 400, the CMP slurry 305 is applied to the exposed surface of the conductive material 122 and the second ILD 111 of the workpiece 400 in order to assist in the removal of the conductive material 122.

By rotating the polishing pad 303 and the workpiece 400 against each other using the CMP slurry 305, the polishing pad 303 along with the assistance of the abrasive 311 in the CMP slurry 305 mechanically grind away the conductive material 122 and the second ILD 111, thereby effectuating a removal of the conductive material 122 and the second ILD 111 at a substantially same rate of removal. As illustrated, in some embodiments, the second ILD 111 is removed after performing the CMP process.

FIGS. 18A-18D illustrate exemplary methods of synthesizing the abrasives, in accordance with some embodiments. As an initial matter, the simple abrasives 321 may be formed using any suitable methods. For example, the simple abrasives 321 may be formed using vapor-phase synthesis, solution-phase synthesis, sol-gel synthesis, hydrothermal methods, the like, or combinations thereof. In addition, these or any suitable methods may be used to synthesize the cores 322X/323X as well as the particulates 323Y which are then used in the processes described below.

Referring to FIG. 18A, the core-shell abrasives 322 may be formed by synthesizing the core 322X, similarly as described above. In some embodiments, a deposition process is performed to form the shell 322Y over an outer surface of the core 322X. The deposition process includes flowing precursors over the core 322X to form a film which becomes the shell 322Y).

For example, the precursors may include a titanium oxide precursor (e.g., to form the shell 322Y of titania) or a silicon oxide precursor (e.g., to form the shell 322Y of silica). The titanium oxide precursor may include Tetrakis (dimethylamido) titanium (TDMA-Ti), and titanium tetrachloride (TiCl₄), the like, or any suitable organic titanium compound (e.g., TiR₁R₂R₃R₄, wherein each R is hydrogen, an alkyl, or an alkoxide), and the silicon oxide precursor may include a silane such as silane tetrachloride (SiCl₄), tris(dimethylamino)silane (TDMAS), bis(ethylmethylamino)silane (BEMAS), bis(diethylamino)silane (BDEAS), the like, or any suitable organic silicon compound (e.g., SiR₁R₂R₃R₄, wherein each R is hydrogen, an alkyl, or an alkoxide). As discussed above, the precursors chemically bond with the core 322X. As a result, Ti—O—Si bonds may compose an initial sub-layer of the shell 322Y, and a film of titania (e.g., for the silica core abrasives 322A) or a film of silica (e.g., for the titania core abrasives 322B) then forms over the core 322X.

Referring to FIGS. 18B-18D, the composite abrasives 323 may be formed by separately synthesizing the core 323X and the particulates 323Y, similarly as described above. In some embodiments, a treatment processes is performed to increase the reactivity of an outer surface of the core 323X and/or outer surfaces of the particulates 323Y, and an application process is performed to sprinkle the particulates 323Y over the outer surface of the core 323X. Similarly as with the core-shell abrasives 322, the treatment process(es) include attaching functional groups to the core 323X and/or the particulates 323Y. It should be appreciated that the treatment processes for the core 323X and the particulates 323Y are performed separately (e.g., in embodiments in which both are performed). The functional groups attached to the core 323X may be considered a core coating 503X, and the functional groups attached to the particulates 323Y may be considered a particulate coating 503Y. The application process includes mixing the core 323X with the particulates 323Y in order to bond the particulates 323Y to the core 323X. The mixing may be performed in dry conditions, in a liquid solvent, or any suitable method. Optionally, after the application process, a post-treatment process may be performed to remove any unreacted functional groups remaining on the outer surfaces of the core 323X and/or the particulates 323Y.

In accordance with some embodiments, the treatment process includes flowing precursors over the core 323X to form the core coating 503X and/or over the particulates 323Y to form the particulate coating 503Y. For example, the precursors may be selected in order to form functional groups such as hydroxyl groups (—OH), amino groups (—NH₂), acyl groups (—OCR), carboxylate groups (—COOH), phosphate (—PO₄), phosphoryl groups (—PO₃), ether groups (—OR), ester groups (—COOR), amide groups (—NRR), silanol groups (—SiOH), thiol groups (—SH), azide-alkyne (—N₃R), and the like. In some embodiments, the precursors may be ionized to form ions and/or plasma of those precursors before flowing the respective precursors over the particles. Note that hydroxyl groups are illustrated, although any of the above functional groups may compose the coatings 503X/503Y.

FIG. 18B illustrates performing treatment processes on both the core 323X and the particulates 323Y before applying the treated particulates 323Y to the treated core 323X to form the composite abrasives 323. FIG. 18C illustrates performing the treatment process on the particulates 323Y before applying the treated particulates 323Y to the core 323X. FIG. 18D illustrates performing the treatment process on the core 323X before applying the particulates 323Y to the treated core 323X.

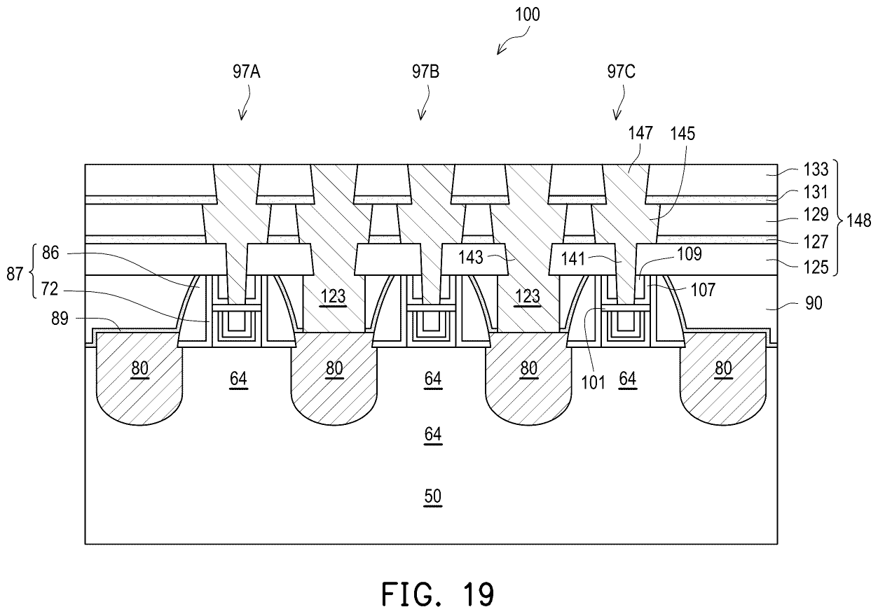

In FIG. 19, an interconnect structure 148 is formed over the first ILD 90 to interconnect the underlying electrical components (e.g., the FinFETs) to form functional circuits. The interconnect structure 148 includes a plurality of dielectric layers (e.g., 125, 129, 133) and conductive features (e.g., 141, 143, 145, 147) formed in the plurality of dielectric layers. Note that in the description herein, unless otherwise specified, conductive features and conductive materials refer to electrically conductive features and electrical conductive materials, respectively.

The dielectric layers 125/129/133 may also be referred to as inter-metal dielectric (IMD) layers. The IMD layers 125/129/133 may be formed of one or more suitable dielectric materials such as silicon oxide, silicon nitride, low-k dielectrics such as carbon doped oxides, extremely low-k dielectrics such as porous carbon doped silicon dioxide, combinations of these, or the like. The IMD layers 125/129/133 may be formed through a process such as chemical vapor deposition (CVD), although any suitable process may be utilized. Etch stop layers 127 and 131 may be formed between adjacent IMD layers. The etch stop layers 127 and 131 may be formed of silicon nitride using PECVD, although other dielectric materials such as nitride, carbide, boride, combinations thereof, or the like, and alternative techniques of forming the etch stop layers, such as LPCVD, PVD, or the like, could alternatively be used.

In FIG. 19, gate contacts 141 are formed to extend through the IMD layer 125, the dielectric material 109, and the semiconductor material 107 to electrically couple to the replacement gate structures 97, e.g., through the capping layer 101. As illustrated, the lower surface of the gate contact 141 physically contacts and extends along the upper surface of the underlying capping layer 101. In addition, upper source/drain contacts 143 are formed to extend through the IMD layer 125 to electrically couple to the contacts 123. In addition, conductive lines 145 and vias 147 formed in IMD layers 129 and 133, respectively. The gate contacts 141, upper source/drain contacts 143, conductive lines 145, and via 147 are formed of one or more conductive materials (e.g., copper, tungsten, cobalt, ruthenium, molybdenum, iridium), and may be formed using any suitable method, such as damascene, dual-damascene, or the like. Note that the number and the location of the conductive features in the interconnect structure 148 are for illustration purpose only and not limiting. Other conductive features at other locations may be formed. In addition, some conductive features formed may not be in the cross-section of FIG. 15, thus are not visible (e.g., shown) in FIG. 19.

In accordance with some embodiments, the gate contacts 141 may be formed similarly as described above in connection with the contacts 123. In particular, a sacrificial oxide (not illustrated) may be deposited over the dielectric layer 125, and gate contact openings may be formed through the sacrificial oxide, the dielectric layer 125, the dielectric material 109, and the semiconductor material 107 to expose the replacement gate structures 97 (e.g., the capping layer 101). In embodiments in which the capping layer 101 is non-conductive (or has a low conductivity), the gate contact openings may be formed through the capping layer 101 to expose the gate electrode 99. A conductive material may then be deposited to fill the gate contact openings. The conductive material may be a similar material as described above in connection with the contacts 123 (e.g., ruthenium). After depositing the conductive material, a removal process is performed to remove portions of the conductive material and the sacrificial oxide above the dielectric layer 125. The remaining conductive material forms the gate contacts 141.

For example, the removal process may include a CMP process similarly as described above. In some embodiments, the CMP process utilizes a slurry that includes any suitable abrasives 311 (or combination thereof) discussed above. However, the abrasives used in the CMP process for the gate contacts 141 may differ from the abrasives used for the contacts 123. Selection of the abrasives and their specific parameters may be based, in part, on a proportion of the sacrificial oxide as compared to the conductive material of the gate contacts 141 along an exposed surface. When the ratio is relatively high, the abrasives may include an increased total exposed surface area of silica. When the ratio is relatively low, the abrasives may include a decreased total exposed surface area of silica. The abrasives therefore may be synthesized and selected in order to perform the CMP process to the desired specifications.

In addition, an analogous CMP process utilizing a slurry of suitable abrasives 311 may be performed in the formation of other conductive features. For example, other portions of the interconnect structure 148 (e.g., the conductive features 143, 145, 147) may be formed of a similar material (e.g., ruthenium) and be subsequently planarized using a selection of the abrasives 311 to remove the respective conductive and dielectric materials at desired rates. It should be appreciated that the abrasives 311 used in the respective CMP slurries 305 for each of the applicable CMP processes may also be selected based on the proportions of conductive material (e.g., ruthenium) and dielectric material (e.g., silicon oxide) being planarized. For example, a CMP process may include abrasives 311 with a high titania-to-silica ratio if increased ruthenium polishing is desired. Conversely, a CMP process may include abrasives 311 with a low titania-to-silica ratio if less ruthenium polishing is desired.

Embodiments may achieve advantages. In accordance with various embodiments, conductive features (e.g., lower source/drain contacts 123, gate contacts 141, or other features of the interconnect structure 148) may comprise ruthenium. After depositing the ruthenium, CMP processes are used to remove excess ruthenium and dielectric material and to planarize the conductive features with the remaining dielectric material. The CMP process may utilize a CMP slurry 305 that contains abrasives 311 comprising titania (e.g., effective at removing excess ruthenium) and a hydrogen peroxide oxidizer (e.g., in complement, effective at preventing staining of the polishing pad 303). To improve effectiveness of removing the dielectric material (e.g., silicon oxide), the abrasives 311 also comprise silica. As a result, the CMP process may be performed more efficiently, more effectively, and at increased yield.

In an embodiment, a method includes forming an opening in a dielectric layer; filling the opening with a conductive material; and performing a chemical mechanical polishing process on the conductive material and the dielectric layer, the chemical mechanical polishing process comprising a slurry, the slurry comprising: abrasives, the abrasives comprising titania-silica hybrid particles; and an oxidizer. In another embodiment, a first core-shell particle of the titania-silica hybrid particles comprises a titania core and a silica shell, and wherein a second core-shell particle of the titania-silica hybrid particles comprises a silica core and a titania shell. In another embodiment, a first composite particle of the titania-silica hybrid particles comprises a plurality of silica particles bonded to a titania carrier particle, and wherein a second composite particle of the titania-silica hybrid particles comprises a plurality of titania particles bonded to a silica carrier particle. In another embodiment, the dielectric layer comprises silicon oxide, and wherein the conductive material comprises ruthenium. In another embodiment, performing the chemical mechanical polishing process comprises removing the silicon oxide and the ruthenium at a same removal rate. In another embodiment, a composite particle of the titania-silica hybrid particles comprises a plurality of silica particles and a plurality of titania particles bonded to a metal oxide particle. In another embodiment, the metal oxide particle comprises at least one of aluminum oxide, zirconium oxide, cesium oxide, or zinc oxide. In another embodiment, the opening extends through the dielectric layer and a lower dielectric layer, and wherein performing the chemical mechanical polishing process comprises removing an entirety of the dielectric layer.

In an embodiment, a chemical mechanical polishing slurry includes a solvent; hybrid abrasive particles dispersed in the solvent, wherein each of the hybrid abrasive particles comprises a silica portion and a titania portion; an oxidizer; a pH adjustor; a pH buffer; and a surfactant. In another embodiment, a first type of the hybrid abrasive particles comprises first silica particles decorated on an outer surface of a first titania carrier particle, and wherein a second type of the hybrid abrasive particles comprises second titania particles decorated on an outer surface of a second silica carrier particle. In another embodiment, each of the hybrid abrasive particles comprises the silica portion being chemically bonded to the titania portion. In another embodiment, the silica portion comprises a silica film, wherein the titania portion comprises a titania particle, and wherein the silica film covers at least a portion of an outer surface of the titania particle. In another embodiment, the titania portion comprises a titania film, wherein the silica portion comprises a silica particle, and wherein the titania film covers at least a portion of an outer surface of the silica particle. In another embodiment, the oxidizer comprises peroxide; wherein the pH adjustor comprises at least one of hydrogen chloride, nitric acid, ammonium hydroxide, or potassium hydroxide; wherein the pH buffer comprises at least one of carboxylic acid, bis-tris methane, or amine; and wherein the surfactant comprises a polymer comprising at least one of amino acid, amine, azole, pyridine, imine, sulfonate, or phosphate.

In an embodiment, a chemical mechanical polishing slurry includes a solvent; an oxidizer; a first hybrid abrasive particle, the first hybrid abrasive particle comprising silica and a first material, the first material being different from silica; and a second hybrid abrasive particle, the second hybrid abrasive particle comprising titania and a second material, the second material being different from titania, the second hybrid abrasive particle having a different structure than the first hybrid abrasive particle. In another embodiment, the first material is titania, and wherein the second material is silica. In another embodiment, the first hybrid abrasive particle comprises a silica core and a titania shell, and wherein the second hybrid abrasive particle comprises a titania core and a silica shell. In another embodiment, the first hybrid abrasive particle comprises a silica core and discrete titania particulates, and wherein the second hybrid abrasive particle comprises a titania core and discrete silica particulates. In another embodiment, the first material is a metal oxide, and wherein the second material is the metal oxide. In another embodiment, the first hybrid abrasive particle comprises a first core and discrete silica particulates, wherein the first core comprises the metal oxide, wherein the second hybrid abrasive particle comprises a second core and discrete titania particulates, and wherein the second core comprises the metal oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a conductive feature in a dielectric layer;
performing a planarization process on the conductive feature and the dielectric layer, the planarization process comprising:
adding abrasives to a polishing slurry, the abrasives comprising titania material bonded to silica material; and
polishing the conductive feature and the dielectric layer using the polishing slurry and the abrasives.

2. The method of claim 1, wherein the conductive feature comprises ruthenium.

3. The method of claim 2, wherein the dielectric layer comprises an oxide.

4. The method of claim 1, wherein a first subset of the abrasives comprises a silica core with a titania shell.

5. The method of claim 4, wherein a second subset of the abrasives comprises a titania core with a silica shell.

6. The method of claim 1, wherein each of the abrasives comprises a silica core with titania particulates attached thereto.

7. The method of claim 6, further comprising forming the abrasives, wherein forming the abrasives comprises reacting the silica core with titania precursors.

8. A method comprising:
forming a transistor over a substrate, the transistor comprising a source/drain region adjacent to a gate structure;
forming an interlayer dielectric over the source/drain region;
etching an opening through the interlayer dielectric to expose the source/drain region;
forming a conductive material in the opening;
forming a slurry comprising an oxidizer and combination abrasives, the combination abrasives comprising a first material and a second material, the first material being different than the second material; and
performing a planarization process to level the interlayer dielectric with the conductive material, the planarization process comprising polishing the interlayer dielectric and the conductive material with the slurry comprising the combination abrasives.

9. The method of claim 8, wherein the first material has a first etch rate for the conductive material, wherein the first material with the oxidizer has a second etch rate for the conductive material, and wherein the second etch rate is greater than the first etch rate.

10. The method of claim 9, wherein the first material has a third etch rate for a dielectric material of the interlayer dielectric, wherein the first material with the oxidizer has a fourth etch rate for the dielectric material, and wherein the third etch rate is greater than the fourth etch rate.

11. The method of claim 10, wherein the first material with the oxidizer and the second material has a fifth etch rate for the dielectric material, and wherein the fifth etch rate is greater than the fourth etch rate.

12. The method of claim 11, wherein the first material comprises titania, wherein the second material comprises silica, and wherein the oxidizer comprises hydrogen peroxide.

13. The method of claim 12, wherein the conductive material comprises ruthenium, and wherein the dielectric material comprises silicon oxide.

14. The method of claim 8, wherein each of the combination abrasives comprises a carrier material with particulates of the first material and the second material bonded thereto, and wherein the carrier material comprises Au, Ag, Al₂O₃, ZrO₂, CeO₂, or ZnO.

15. A method comprising:
forming an opening in a dielectric material to expose a semiconductor material;
forming a conductive material in the opening;
performing a first planarization process using a first slurry to remove portions of the dielectric material and the conductive material, the first slurry comprising first abrasives and an oxidizer, each of the first abrasives comprising titania and silica, each of the first abrasives having a first proportion of surface areas between titania and silica; and
after performing the first planarization process, performing a second planarization process using a second slurry to remove additional portions of the dielectric material and the conductive material, the second slurry being different than the first slurry, the second slurry comprising second abrasives and the oxidizer, each of the second abrasives comprising titania and silica, each of the second abrasives having a second proportion of surface areas between titania and silica, the second proportion being different than the first proportion.

16. The method of claim 15, further comprising, before performing the first planarization process, performing a preliminary planarization process to level the dielectric material and the conductive material, wherein the preliminary planarization process uses a preliminary slurry, and wherein the preliminary slurry is different than the first slurry and the second slurry.

17. The method of claim 15, wherein each of the first abrasives comprises a titania core with silica material bonded over a surface of the titania core.

18. The method of claim 17, wherein each of the second abrasives comprises a silica core with titania material bonded over a surface of the silica core.

19. The method of claim 15, wherein the conductive material comprises ruthenium, and wherein the dielectric material comprises an oxide.

20. The method of claim 19, wherein the oxidizer comprises hydrogen peroxide.
